(19) United States
(12) Patent Application Publication
(10) Pub. No.: US 2026/0121587 A1
(43) Pub. Date: Apr. 30, 2026

(54) AUDIO BIASING AMPLIFIER

(71) Applicant: TEXAS INSTRUMENTS INCORPORATED, Dallas, TX (US)

(72) Inventors: Syed HAMEED, Hyderabad (IN); Jyoti RAJ, New Delhi (IN); Anand SUBRAMANIAN, Dallas, TX (US)

(21) Appl. No.: 19/255,077

(22) Filed: Jun. 30, 2025

(30) Foreign Application Priority Data
Oct. 25, 2024 (IN) 202441081460

(51) Int. Cl. H03F 1/26

(52) U.S. Cl. CPC H03F 1/26; H03F 2200/03

(57) ABSTRACT

In an embodiment, a device including: first and second terminals; an amplifier having an input and an output; first and second switches coupled to the output of the amplifier, a first resistor coupled between the first switch and the first terminal; a second resistor coupled between the second switch and the second terminal; a third switch coupled to the input of the amplifier, and a fourth switch coupled to the input of the amplifier.

### CROSS-REFERENCE TO RELATED APPLICATIONS

The present application claims priority to India Provisional Patent Application No. 202441081460, which was filed Oct. 25, 2024, is titled “NOISE AND POWER REDUCTION TECHNIQUE FOR A MICROPHONE BIASING AMPLIFIER,” and is hereby incorporated herein by reference in its entirety.

### TECHNICAL FIELD OF THE INVENTION

The present disclosure relates generally to an electronic system and method, and, in particular examples, to an audio biasing amplifier.

### BACKGROUND

Headphones and microphones with jacks connect to audio devices (e.g., smartphones, laptop computers, tablets) through a plug that carries analog signals. Microphones may produce signals with low amplitude that may require conditioning. A biasing amplifier may increase the signal strength for compatibility with downstream circuits. The amplifier may adjust the signal level to meet the input requirements of audio processing equipment. This may enable effective reception of microphone audio signals through the jack interface.

### SUMMARY

In accordance to an embodiment, a device includes: first and second terminals; an amplifier having an input and an output; first and second switches coupled to the output of the amplifier; a first resistor coupled between the first switch and the first terminal; a second resistor coupled between the second switch and the second terminal; a third switch coupled to the input of the amplifier; and a fourth switch coupled to the input of the amplifier.

In accordance to an embodiment, a device includes: a first terminal; an amplifier having an output and first and second inputs, the first input of the amplifier coupled to the first terminal; a feedback path coupled between the output of the amplifier and the second input of the amplifier; and a first transistor having a control terminal coupled to the first input of the amplifier, and a current path coupled between the second input of the amplifier and the first terminal.

In accordance to an embodiment, a device includes: an audio jack port having first, second, third, and fourth terminals; an audio transmit circuit coupled to the first, second, and third terminals of the audio jack port and capable of providing first and second audio signals to the first and second terminals of the audio jack port, respectively, the third terminal of the audio jack port capable of providing a return path for the first and second audio signals; an audio receive circuit coupled to the third and fourth terminals of the audio jack port and capable of receiving a third audio signal from the fourth terminal of the audio jack port, the third terminal of the audio jack port capable of providing a return path for the third audio signal; a first capacitor coupled to the third terminal of the audio jack port and the audio receive circuit; a second capacitor coupled to the fourth terminal of the audio jack port and the audio receive circuit; and an amplifier having an input and an output, the input of the amplifier coupled to the first capacitor, and the output coupled to the second capacitor and the fourth terminal of the audio jack port.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a block diagram of an audio system including an audio biasing amplifier, in accordance with various examples;

FIG. 2 is a schematic diagram of an audio headset configured to operate with an audio biasing amplifier, in accordance with various examples;

FIG. 3 is a circuit schematic diagram of an audio device including an audio biasing amplifier, in accordance with various examples;

FIG. 4 is a circuit schematic diagram of a portion of an audio device, in accordance with various examples;

FIG. 5 is a timing diagram depicting the switching operation of a portion of an audio device that includes an audio biasing amplifier, in accordance with various examples; and

FIG. 6 is a schematic diagram of a circuit for powering switches in an audio device including an audio biasing amplifier, in accordance with various examples.

Corresponding numerals and symbols in different figures generally refer to corresponding parts unless otherwise indicated. The figures are drawn to clearly illustrate relevant aspects of preferred examples and are not necessarily drawn to scale.

### DETAILED DESCRIPTION

The making and using of the examples disclosed are described in detail below. The present disclosure provides many applicable inventive concepts that can be embodied in a wide variety of specific contexts. The specific examples described are merely illustrative of specific ways to make and use the invention(s), and do not limit the scope of the invention(s).

The description below illustrates the various specific details to provide an in-depth understanding of several examples according to the description. The examples may be obtained without one or more of the specific details, or with other methods, components, materials and the like. In other cases, known structures, materials or operations are not shown or described in detail so as not to obscure the different aspects of the examples. References to “an example” in this description indicate that a particular configuration, structure or feature described in relation to the example is included in at least one example. Consequently, phrases such as “in one example” that may appear at different points of the present description do not necessarily refer exactly to the same example. Furthermore, specific formations, structures or features may be combined in any appropriate manner in one or more examples.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Some embodiments relate to an audio biasing amplifier with reduced power consumption and noise.

An audio headset typically includes headphones and a microphone. The audio headset may also include a jack that couples to a port in an audio device, such as a laptop computer, a tablet, or a smartphone. The audio device provides audio signals to the headphones via the port and the jack. The headphones play audible sounds (e.g., music) according to the audio signals. Similarly, the microphone provides audio signals to the audio device via the port and the jack. The audio device processes and/or stores the audio signals from the microphone.

In many cases, the jack includes four distinct electrical terminals separated from each other by non-conductive material. Two of these terminals provide audio signals from the audio device to the headphone of the audio headset. A third terminal provides audio signals from the microphone to the audio device. The fourth terminal is a reference terminal (e.g., connected to ground) that is shared by the headphones and the microphone. Because the reference terminal is shared by the audio pathways for the headphones and the microphone, crosstalk can occur. For example, an audio signal provided to the headphones is returned via the reference terminal, and because this reference terminal is also used by the audio pathway of the microphone, the audio signal returned from the headphones may couple into the audio pathway of the microphone. This may result in distortion of the audio data captured by the microphone. For example, a voice command captured by the microphone may become distorted.

Certain audio device architectures present technical challenges beyond the crosstalk challenges described above, such as the introduction of noise and excessive power consumption. For example, such audio device architectures include a bias amplifier that applies a bias signal to the microphone audio signal to prepare the microphone audio signal for subsequent processing. This bias amplifier includes a feedback path having one or more resistors, which may introduce thermal noise into the bias signal. Furthermore, the bias amplifier may introduce input referred noise, which is amplified and provided in the bias signal at the bias amplifier output. Further still, resistors in the bias amplifier feedback path may dissipate significant amounts of power. Specifically, resistance values of feedback path resistors may be decreased to achieve reduced noise resistance, but this increases the current flowing through the feedback path resistors, and thus increases the power consumption by the feedback path resistors.

Some embodiments relate to an audio biasing amplifier with power consumption and noise, including crosstalk, that are reduced relative to other solutions. The audio biasing amplifier includes transistors (e.g., field effect transistors (FETs), such as metal oxide semiconductor FETs (MOSFETs)) in the feedback path of the amplifier. The feedback path of the amplifier also includes resistors. The combination of the transistors and resistors in the amplifier feedback path consumes an amount of power x (for a given noise resistance y) that may advantageously be less than the power n consumed in a resistors-only feedback path (for the same noise resistance y). Some or all of this relative reduction in power consumption may be traded for a reduction in noise resistance, thereby substantially reducing power consumption, or else substantially reducing noise resistance, or else modestly reducing both power consumption and noise resistance.

Some embodiments include a transistor coupled to the feedback path that prevents the gain provided by the feedback path from increasing amplifier noise (e.g., input referred noise). Further, for the same level of power consumption, the thermal noise introduced by the combination of transistors and resistors in the feedback path may advantageously be substantially less than the thermal noise of a resistors-only feedback path, because the transistor can be sized to achieve a target noise resistance, which may not be possible with resistors, which have a fixed resistance.

Some embodiments include a switch network that facilitates chopping to mitigate any flicker noise that might be introduced by transistors in the feedback path.

In some embodiments, the crosstalk described above is mitigated by coupling the crosstalk on the reference node into the audio biasing amplifier, which produces a bias signal that also includes the crosstalk. Because both the bias signal and the reference signal include the same phase-matched crosstalk, the deleterious effect of the crosstalk may be reduced or eliminated.

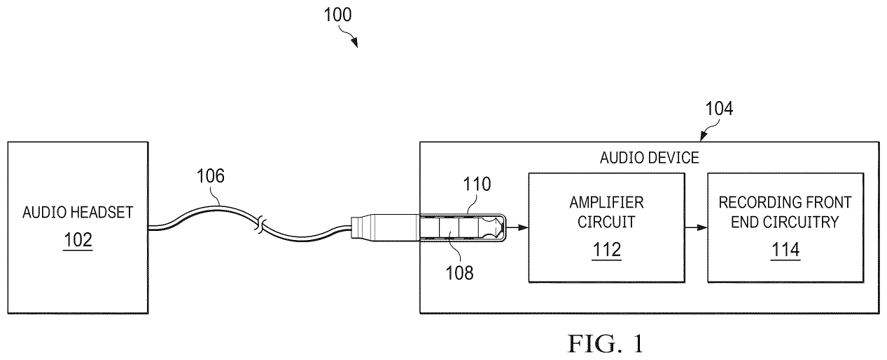

FIG. 1 is a block diagram of an audio system 100 including an audio biasing amplifier, according to an embodiment of the present disclosure. In particular, the audio system 100 includes an audio headset 102 and an audio device 104. The audio headset 102 may include headphones and a microphone, for example. Examples of the audio device 104 include laptop computers, tablets, and smartphones. In at least some examples, the audio device 104 is a portable, battery-powered device. The audio headset 102 is coupled to the audio device 104 by a cable 106 that terminates in an audio jack 108. The audio jack 108 couples to a port 110 in the audio device 104. The audio jack port 110 is coupled to an amplifier circuit 112. Audio processing front end circuitry 114 is coupled to the amplifier circuit 112. Additional circuitry may be coupled to the audio processing front end circuitry 114. As described in greater detail below, the amplifier circuit 112 is configured to provide a bias signal to a microphone audio signal received from the audio headset 102. The amplifier circuit 112 includes specific components as described herein that may advantageously reduce power consumption, noise, and crosstalk relative to other solutions, thereby significantly improving audio quality while reducing battery consumption.

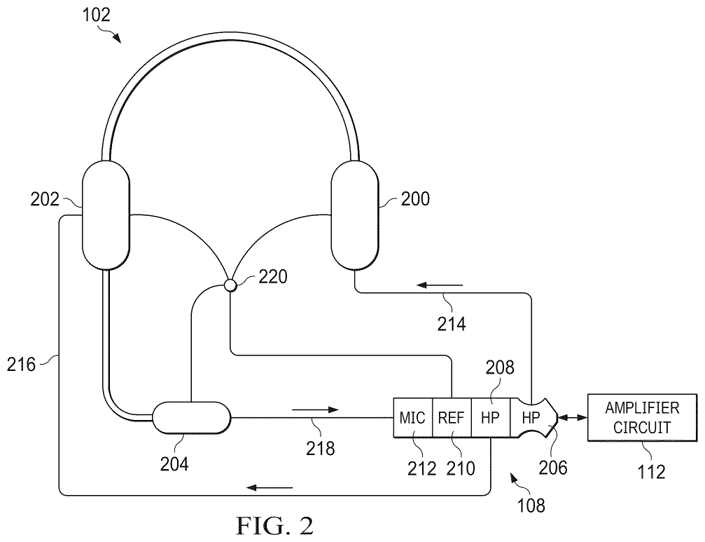

FIG. 2 is a schematic diagram of the audio headset 102 configured to operate with an audio biasing amplifier, according to an embodiment of the present disclosure. The audio headset 102 includes headphones 200 and 202 and a microphone 204. FIG. 2 also depicts the audio jack 108, which includes terminals 206, 208, 210, and 212. The terminals 206, 208, 210, and 212 are electrically isolated from each other. The terminals 206 and 208 are configured to provide headphone audio signals to the audio headset 102, and thus the terminals 206 and 208 are coupled to the headphones 200 and 202 via audio pathways 214 and 216. Accordingly, the terminals 206 and 208 may be referred to herein as the headphone terminals. The terminal 212 is configured to receive a microphone signal from the audio headset 102, and thus the terminal 212 is coupled to the microphone 204 via audio pathway 218. Accordingly, the terminal 212 may be referred to herein as the microphone terminal. The terminal 210 is configured to provide a reference node to the audio headset 102, and thus the terminal 210 is coupled to a node 220, which, in turn, is coupled to the headphones 200 and 202 and to the microphone 204. Accordingly, the terminal 210 may be referred to herein as the reference terminal. The microphone 204 captures audio signals (e.g., speech, music) and provides the audio signals along the audio pathway 218 to the terminal 212, using the node 220 and the terminal 210 as a reference node. Because this reference node (also referred to herein as a return path) is shared by the headphones 200 and 202 and the microphone 204, audio signals provided to the headphones 200 and 202 are coupled into the reference node, and thus are also coupled into the audio biasing amplifier in the amplifier circuit 112, resulting in crosstalk between the audio signals provided to the headphones 200 and 202, and the audio signals received from the microphone 204. As described below, the amplifier circuit 112 may advantageously mitigate this crosstalk by coupling the crosstalk into the bias signal generated by the amplifier circuit 112 and applied to the audio signal received from the microphone 204 via the terminal 212. The amplifier circuit 112 also may also mitigate noise and power consumption as described in greater detail below.

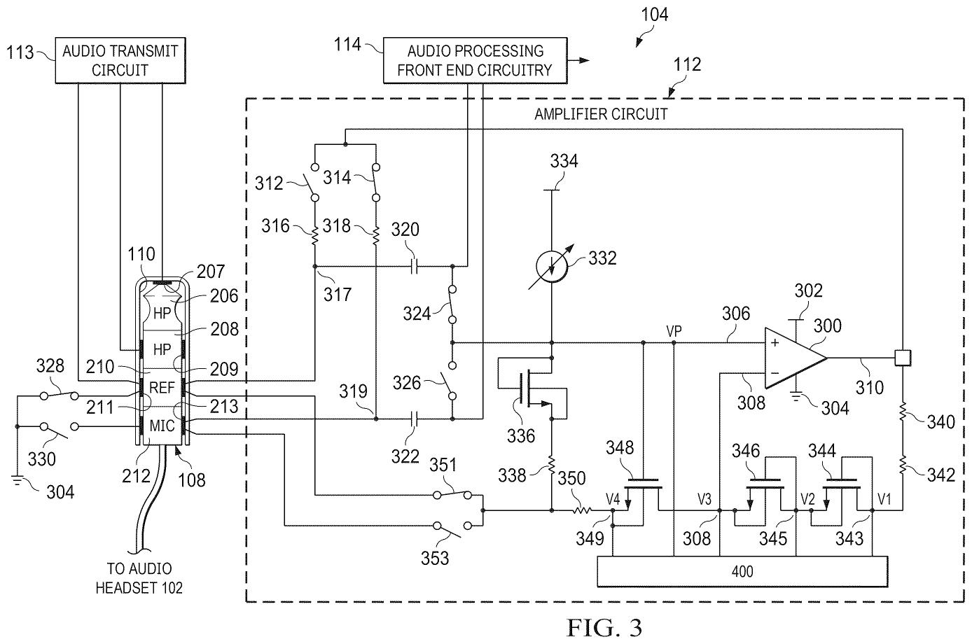

FIG. 3 is a circuit schematic diagram of the audio device 104 including an audio biasing amplifier, according to an embodiment of the present disclosure. More particularly, the audio device 104 includes the audio jack 108, the amplifier circuit 112 coupled to the audio jack 108, and the audio processing front end circuitry 114 coupled to the amplifier circuit 112. The audio jack port 110 includes terminals 207, 209, 211, and 213, which contact the terminals 206, 208, 210, and 212, respectively. Thus, a component coupled to terminal 206 is also coupled to terminal 207, and vice versa; a component coupled to terminal 208 is also coupled to terminal 209, and vice versa; a component coupled to terminal 210 is also coupled to terminal 211, and vice versa; and a component coupled to terminal 212 is also coupled to terminal 213, and vice versa. Thus, such couplings should be interpreted to be synonymous with each other. The terminals 207, 209, and 211 are coupled to an audio transmit circuit 113, which includes circuitry useful to generate, modulate, and/or provide audio signals to the headphones 200, 202 (FIG. 2) using the headphone terminals 206, 208 and the reference terminal 210. The amplifier circuit 112 includes a biasing amplifier 300, a voltage source 302 coupled to the biasing amplifier 300, and a ground terminal 304 coupled to the biasing amplifier 300. The biasing amplifier 300 includes a non-inverting input, an inverting input, and an output. A connection 306 is coupled to the non-inverting input of the biasing amplifier 300, and a connection 308 is coupled to the inverting input of the biasing amplifier 300. A connection 310 is coupled to the output of the biasing amplifier 300.

In examples, the amplifier circuit 112 includes switches 312 and 314. Like all switches shown and described herein, the switches 312, 314 may include transistors, such as FETs (e.g., MOSFETs). The various switches described herein, such as the switches 312, 314, may be controlled by any suitable entity and at any suitable time, for example, during manufacture by manufacturing equipment (in which case the switches' open/closed states remain unchanged during operation), or dynamically during operation, e.g., by a microcontroller, processor, or other type of control circuit. A resistor 316 is coupled to the switch 312, and a resistor 318 is coupled to the switch 314. The resistor 316 is coupled to a connection 317, and the resistor 318 is coupled to a connection 319. The connection 317 is coupled to the terminal 210 (e.g., the reference node described above; equivalent to being coupled to the terminal 211), and the connection 319 is coupled to the terminal 212 (e.g., to the microphone 204 (FIG. 2); equivalent to being coupled to the terminal 213).

The amplifier circuit 112 further includes a capacitor 320 coupled to the connection 317, and a capacitor 322 coupled to the connection 319. A switch 324 is coupled to the capacitor 320, and both the switch 324 and the capacitor 320 are coupled to a first input of the audio processing front end circuitry 114. A switch 326 is coupled to the capacitor 322, and both the switch 326 and the capacitor 322 are coupled to a second input of the audio processing front end circuitry 114. The connection 306 is coupled between the switches 324 and 326, as shown.

A switch 328 is coupled to the terminal 210 (e.g., the reference node), and a switch 330 is coupled to the terminal 212 (e.g., the microphone 204 (FIG. 2)). The ground terminal 304 is coupled to the switches 328 and 330. In examples, the switches 328, 330, and the ground terminal 304 are considered to be part of the amplifier circuit 112.

The amplifier circuit 112 includes a current source 332, a voltage source 334 coupled to the current source 332 and to the connection 306, a transistor 336 (e.g., a diode-connected FET, which, in some examples, may be replaced by a diode) coupled to the connection 306, and a resistor 338 coupled to the transistor 336. The amplifier circuit 112 includes a feedback path between the connection 310 and the connection 308 (i.e., between the output of the biasing amplifier 300 and the inverting input of the biasing amplifier 300). The feedback path includes a resistor 340 coupled to the connection 310, a resistor 342 coupled to the resistor 340, a connection 343 coupled to the resistor 342, a transistor 344 (e.g., a diode-connected FET, which, in some examples, may be replaced by a diode) coupled to the connection 343, a connection 345 coupled to the transistor 344, and a transistor 346 (e.g., a diode-connected FET, which, in some examples, may be replaced by a diode) coupled to the connection 345. In examples, the resistors and transistors in the feedback path are equal in number. The connection 308 is coupled to the transistor 346. The amplifier circuit 112 includes a transistor 348 (e.g., a FET) coupled to the connection 308, to the connection 306, and to a connection 349. In examples, the transistors 344, 346, and 348 are matched to each other (e.g., size- and type-matched FETs). The connection 349 is coupled to a resistor 350, and the resistor 350 is coupled to the resistor 338. In examples, the resistors 340, 342, and 350 are matched to each other (e.g., identical resistances). The resistors 338 and 350 are coupled to switches 351 and 353. The switch 351 is coupled to the terminal 210 and the connection 317. The switch 353 is coupled to the terminal 212 and the connection 319. The connection 310 is coupled to the switches 312 and 314.

As described above, the terminal 210 is configured to operate as the reference node, and the terminal 212 is configured to receive the microphone audio signal. Accordingly, the switch 328 is closed and the switch 330 is open, so that the terminal 210 is coupled to the ground terminal 304, and the terminal 212 is not coupled to the ground terminal 304. Further, for the same reason, the switch 351 is closed and the switch 353 is open, so that the resistors 338 and 350 are coupled to the ground terminal 304 via the terminal 210, and the resistors 338 and 350 are not coupled to the terminal 212 and the connection 319. The switch 312 is open and the switch 314 is closed, so that the bias signal provided by the biasing amplifier 300 is coupled into the connection 319 and not into the connection 317 (i.e., the reference node). Although the terminals 210 and 212 are the reference and microphone terminals, respectively, in some examples, the roles of the terminals 210 and 212 are swapped, such that the terminal 210 is the microphone terminal and the terminal 212 is the reference terminal. The switches 328, 330, 351, 353, 312, and 314 are present to accommodate such variability in the roles of the terminals 210 and 212. Because the terminals 210 and 212 are reference and microphone terminals in the example of FIG. 3, the switches 328, 351, and 314 are closed and the switches 330, 353, and 312 are open. Had the terminal 210 been the microphone terminal and the terminal 212 been the reference terminal, the switches 328, 351, and 312 would be open, and the switches 330, 353, and 312 would be closed.

Still referring to FIG. 3, in operation, a microphone audio signal is received via the microphone terminal 212 and is provided to the audio processing front end circuitry 114 via the connection 319 and capacitor 322. Similarly, the reference terminal 210 is coupled to the ground terminal 304 via the switch 328, and thus the reference terminal 210 provides ground to the audio processing front end circuitry 114 via the connection 317 and the capacitor 320.

The microphone audio signal on the connection 319 should be appropriately biased prior to entering the audio processing front end circuitry 114, so that the audio processing front end circuitry 114 may appropriately process the microphone audio signal. The biasing amplifier 300 provides this bias signal on connection 310, which, as described above, is coupled to the connection 319 via the switch 314 and the resistor 318.

To generate the bias signal, the biasing amplifier 300 receives a reference voltage at the non-inverting input via the connection 306. The reference voltage is provided by the combination of the voltage source 334 and the variable current source 332, which may include a transistor (e.g., FET) in some examples. The current source 332 may be trimmed during manufacturing to mitigate process variations. Such a transistor may be turned on more or less strongly to provide a variable current, and this current may be selected during manufacture, for example. The transistor 336 is a diode-connected transistor, meaning that the transistor 336 operates similarly to a diode. When the voltage drop across the transistor 336 exceeds a threshold voltage, the transistor 336 turns on, permitting current flow through the resistor 338 and to the ground terminal 304 via the reference terminal 210. Depending on the states of the current source 332 and the transistor 336, the reference voltage is formed on the connection 306. The capacitor 320 operates as a low-pass filter to attenuate noise in the reference voltage on the connection 306 (e.g., the voltage generated by the current source 332 and the resistor 338), thereby facilitating a steady reference voltage. The biasing amplifier 300 drives the bias signal on the connection 310 in an attempt to equalize the voltages at the inverting and non-inverting inputs. The resistors 340 and 342 and the transistors 344 and 346 have a first combined resistance, and the transistor 348 and the resistor 350 have a second combined resistance. The connection 308 couples in between the first and second combined resistances, resulting in a voltage divider that includes the first and second combined resistances and the connections 310 and 308. Assuming that the voltage on the connection 306 is adequately high to turn on the transistor 348, and further assuming that the voltage drops across the transistors 344 and 346 (both of which are diode-connected transistors) are adequate to turn on the transistors 344 and 346, the voltage on the connection 308 is given by the voltage divider formula. Specifically, the voltage on the connection 308 is the ratio of the second combined resistance over the sum of the first and second combined resistances, multiplied by the voltage on the connection 310. Thus, either or both of the first and second combined resistances may be adjusted to achieve a target gain in the feedback path between the connections 310 and 308.

As described above, existing audio biasing amplifiers suffer from multiple technical challenges, including crosstalk, noise, and power consumption. The manner in which the amplifier circuit 112 mitigates these technical challenges is now described in greater detail.

The amplifier circuit 112 may mitigate crosstalk as follows. As described above, the reference terminal 210 is shared among the headphone terminals 206 and 208 and the microphone terminal 212. Consequently, crosstalk from the headphone audio pathways is coupled into the reference terminal 210, and the audio processing front end circuitry 114 receives this crosstalk via the connection 317. If the crosstalk were also coupled into the microphone audio signal on the microphone terminal 212 and the connection 319, the crosstalk on the connection 319 would negate the crosstalk on the connection 317. To achieve this, the switch 324 is closed, thereby coupling the connection 317 (which includes the crosstalk from the reference terminal 210) to the connection 306. Consequently, the crosstalk is added to the reference voltage already present on the connection 306. The crosstalk is not filtered out by the capacitor 320 because the crosstalk is present on both terminals of the capacitor 320. Because the crosstalk is present at the non-inverting input of the biasing amplifier 300, the crosstalk will also be present on the output of the biasing amplifier 300, as the biasing amplifier 300 drives the voltage on the output in an effort to have the non-inverting and inverting inputs match each other. Thus, the crosstalk is present in the bias signal on the connection 310. This bias signal, which includes the crosstalk, is coupled to the connection 319, and thus the crosstalk is now present on both connections 317 and 319, and thus is negated. No meaningful phase delay is present for the crosstalk in connection 319, as phase delay generally appears at very high frequencies (e.g., 500 kHz), not in the audio frequency range.

The amplifier circuit 112 may also mitigates power consumption and noise resistance. In prior solutions, the feedback path between the amplifier output and inverting input includes a variable resistor, which can be set to achieve a target gain in the feedback path. However, resistors may introduce a significant degree of noise resistance, and thus noise. This noise resistance can be decreased by decreasing the resistance values of the resistors in the feedback path. However, decreasing the resistance in this manner comes with a tradeoff in the form of increased current, and thus, increased power consumption. Thus, reducing noise increases power consumption, and reducing power consumption increases noise.

In some embodiments, the feedback path includes a combination of resistors and transistors (e.g., the resistors 340, 342 and the transistors 344, 346). Transistors, particularly FETs, differ from resistors in that they consume significantly less current for a given noise resistance. Thus, for example, if the combination of resistors and transistors in the feedback path shown in FIG. 3 were adjusted to have a total noise resistance equal to that of a resistor-only feedback path, the power consumption for the combination of resistors and transistors is substantially less than the power consumption for the resistors only. Thus, the tradeoff between power consumption and noise resistance is more advantageous for transistors than for resistors. Because the power consumption for the combination of transistors and resistors is less than for resistors-only for a given noise resistance, significant power savings are realized. Furthermore, some or all of these power savings can be sacrificed in exchange for decreased noise resistance. Thus, for instance, a balance can be achieved that reduces both power consumption and noise (e.g., thermal noise) relative to a resistor-only feedback path. The same principle may be applied elsewhere in the amplifier circuit 112 to achieve similar technical advantages, such as with the transistor 348 and the resistor 350, for example.

The amplifier circuit 112 may also mitigates amplifier noise. As described above, the capacitor 320 filters and steadies the reference voltage present on the connection 306. However, the biasing amplifier 300 may introduce some degree of input referred noise at the non-inverting input (at least some of the input referred noise is generated elsewhere in the biasing amplifier 300, but is considered or “referred” as having been generated at the input). Because the biasing amplifier 300 operates in an attempt to equalize the voltages at the non-inverting and inverting inputs, there is said to be a virtual short between the non-inverting and inverting inputs, and thus the input referred noise that is at the non-inverting input is also present at the inverting input, and thus on the connection 308. Although the input referred noise is present on the non-inverting input of the biasing amplifier 300, the input referred noise is not present on the connection 306, as the reference voltage is held steady by the capacitor 320. Consequently, the reference voltage applied to the gate terminal of transistor 348 is steady, and the voltage at the source terminal of transistor 348 is also steady, because the source terminal is coupled to the ground terminal 304 via the resistor 350. When the gate-to-source voltage (Vgs) of a transistor, such as the transistor 348, is steady, and the signal at the drain terminal (e.g., connection 308) is experiencing noise, the transistor 348 appears to the noise on the drain terminal (e.g., connection 308) to have a very large resistance. If the voltage divider formula is calculated for the feedback path of the biasing amplifier 300 assuming the resistance of the transistor 348 is very large, the ratio of the resistance of the second combined resistance (i.e., resistors 340, 342 and transistors 344, 346) to the sum of the first and second combined resistances (i.e., resistors 340, 342, transistors 344, 346, transistor 348, and resistor 350) converges to unity, and the voltage on connection 310 is approximately equal to the voltage on connection 308. Thus, from the perspective of the amplifier noise mentioned above that is present at the inputs of the biasing amplifier 300 and the output of the biasing amplifier 300, there is no gain to be applied via the feedback path, because the amplifier noise present at the connection 310 is, e.g., identical to that present at the connection 308. In this way, feedback path amplification of amplifier noise is eliminated.

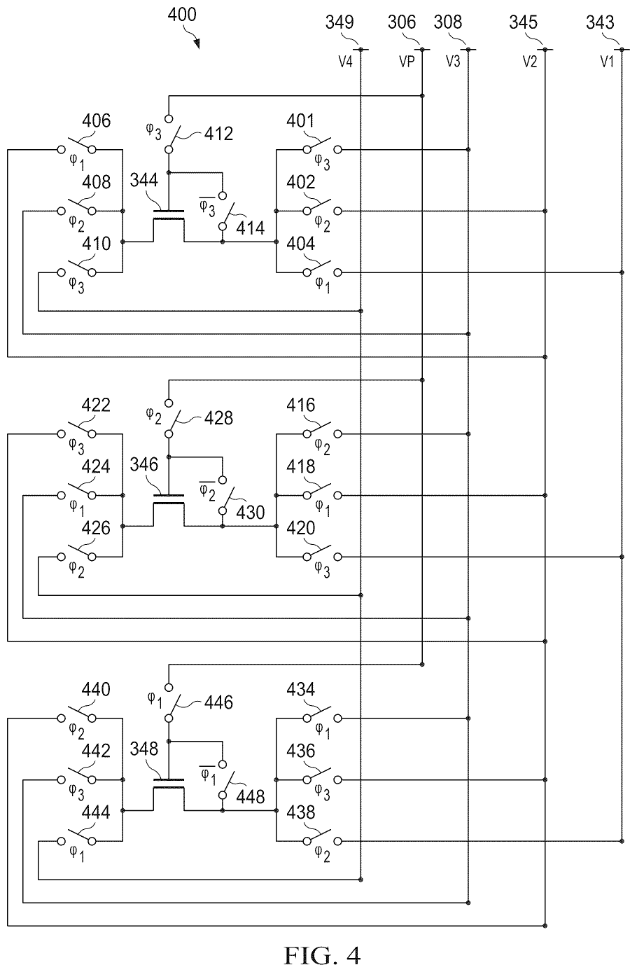

The amplifier circuit 112 may also mitigate flicker noise. The presence of transistors 344, 346, and 348 (e.g., FETs) can contribute to flicker noise, which is a low-frequency noise caused by charge trapping and detrapping at the semiconductor-oxide interface. A chopping technique is useful to mitigate this flicker noise. FIG. 4 is a circuit schematic diagram of chopping circuit 400, according to an embodiment of the present disclosure. Chopping circuit 400 may be implemented as part of amplifier circuit 112, e.g., as shown in FIG. 3.

The chopping circuit 400 includes a network of switches that effectively rotates the sequence of the transistors 344, 346, and 348. For example, during a first clock phase, the network of switches positions the transistors 344, 346, and 348 as shown in FIG. 3. During a second clock phase, the network of switches replaces transistor 346 with transistor 344, transistor 348 with transistor 346, and transistor 344 with transistor 348. During a third clock phase, the network of switches again replaces transistor 346 with transistor 344, transistor 348 with transistor 346, and transistor 344 with transistor 348. Such chopping by rapidly swapping matched transistors suppresses flicker noise by averaging out the transistors' individual low-frequency noise contributions. Because flicker noise changes slowly, fast switching causes the flicker noise to cancel over time.

The chopping circuit 400 includes a switch 401 coupled to connection 308, a switch 402 coupled to connection 345, a switch 404 coupled to connection 343, a switch 406 coupled to connection 345, a switch 408 coupled to connection 308, and a switch 410 coupled to connection 349, a switch 414 coupled to the switches 401, 402, and 404 and to the gate terminal of the transistor 344, and a switch 412 coupled to connection 306 and to the gate terminal of the transistor 344.

Switches 416, 418, 420, 422, 424, 426, 428, and 430 are coupled, e.g., identically, to their respective counterparts described above, and thus these couplings are not described again. Switches 434, 436, 438, 440, 442, 444, 446, and 448 are coupled, e.g., identically, to their respective counterparts described above, and thus these couplings are not described again.

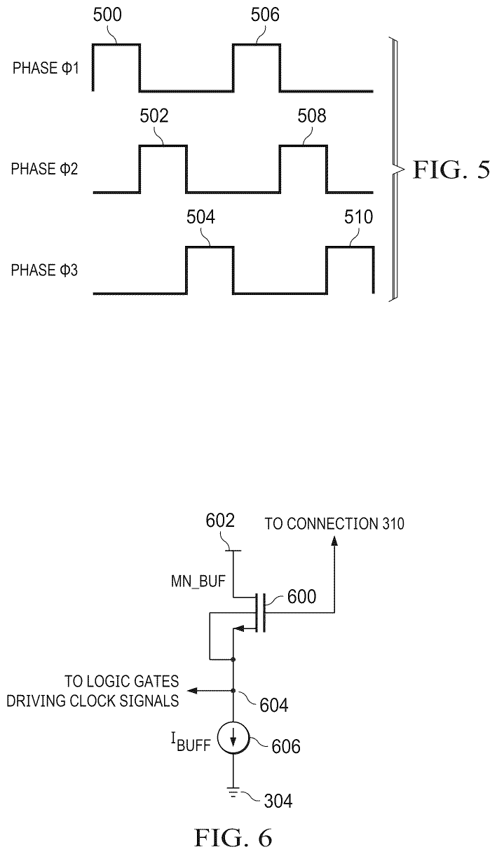

The various switches of the chopping circuit 400 are operated according to alternating clocks φ1, φ2, and φ3. FIG. 5 is a timing diagram depicting φ1, φ2, and φ3, according to an embodiment of the present disclosure. The clocks alternate, meaning that when φ1 is high (e.g., pulses 500 and 506), φ2 and φ3 are low, and when φ2 is high (e.g., pulses 502 and 508), ¢1 and φ3 are low, and when φ3 is high (e.g., pulses 504 and 510), φ1 and φ2 are low.

Referring simultaneously to FIGS. 4 and 5, when φ1 goes high, φ2 and φ3 are low. Thus, switches 404, 406, 418, 424, 434, and 444 are closed, while the switches controlled by φ2 and φ3 are open, the switches 414 and 430 are closed, and the switch 448 is open. In this state, the transistor 344 is coupled between connections 343 and 345, and the switch 414 is closed, thereby placing the transistor 344 in a diode-connected configuration. The transistor 346 is coupled between connections 345 and 308, and the switch 430 is closed, placing the transistor 346 in a diode-connected configuration. The transistor 348 is coupled between connections 308 and 349, and the switch 446 is closed while the switch 448 is open, which couples the gate terminal of the transistor 348 to the connection 306.

When φ2 goes high, φ1 and φ3 are low. Thus, switches 402, 408, 416, 426, 438, 440, 414, 428, and 448 are closed, while the remaining switches are open. In this state, the transistor 344 is coupled between the connections 345 and 308, and because switch 414 is closed, the transistor 344 is in a diode-connected configuration. The transistor 346 is coupled between the connections 308 and 349, and because switch 430 is open, the transistor 346 is not in a diode-connected configuration. Because switch 428 is closed, the gate terminal of the transistor 346 is coupled to connection 306. The transistor 348 is coupled between the connections 343 and 345, and because the switch 448 is closed, the transistor 348 is in a diode-connected configuration.

When φ3 goes high, φ1 and φ2 are low. Thus, switches 401, 410, 420, 422, 436, 442, 412, 430, and 448 are closed, while the remaining switches are open. In this state, the transistor 344 is coupled between connections 308 and 349, while the gate terminal of the transistor 344 is coupled to the connection 306. The transistor 346 is coupled between connections 343 and 345, and the transistor 346 is in a diode-connected configuration. The transistor 348 is coupled between connections 345 and 308, with the transistor 348 coupled in a diode-connected configuration.

The switching pattern shown in FIG. 5 is repeated at a high frequency, causing the transistors 344, 346, and 348 to be rapidly coupled and decoupled as described above. This produces the desired chopping effect, which mitigates flicker noise as described above.

FIG. 6 is a schematic diagram of a circuit for powering switches in an audio device including an audio biasing amplifier with reduced power consumption and noise. More particularly, FIG. 6 shows a buffer circuit useful for powering the switches in the switching network of the chopping circuit 400 (FIG. 4). The buffer circuit includes a transistor 600 (e.g., a FET) having a gate terminal coupled to the connection 310 (FIG. 3), a drain terminal coupled to a voltage source 602, and a source terminal coupled to a connection 604. The connection 604 is coupled to a current source 606, which is coupled to the ground terminal 304 (FIG. 3). The connection 604 is coupled to the switches in the switching network of the chopping circuit 400. The buffer circuit provides power to logic gates (not expressly shown) that drive the clock signals φ1, φ2, and φ3. The buffer circuit prevents degradation of the distortion performance of the crosstalk signal feedback path at connection 310.

Example embodiments of the present disclosure are summarized here. Other embodiments can also be understood from the entirety of the specification and the claims filed herein.

Example 1. A device including: first and second terminals; an amplifier having an input and an output; first and second switches coupled to the output of the amplifier; a first resistor coupled between the first switch and the first terminal; a second resistor coupled between the second switch and the second terminal; a third switch coupled to the input of the amplifier; and a fourth switch coupled to the input of the amplifier.

Example 2. The device of example 1, where the third switch is configured to be open when the fourth switch is closed, and where the fourth switch is configured to be open when the third switch is closed.

Example 3. The device of one of examples 1 or 2, where the first switch is configured to be open when the second switch is closed, and where the second switch is configured to be open when the first switch is closed.

Example 4. The device of one of examples 1 to 3, where the first and fourth switches are configured to be open when the second and third switches are closed, and where the second and third switches are configured to be open when the first and fourth switches are closed.

Example 5. The device of one of examples 1 to 4, further including: a fifth switch coupled between the first terminal and ground; and a sixth switch coupled between the second terminal and ground.

Example 6. The device of one of examples 1 to 5, where the fifth switch is configured to be open when the second switch is closed, and where the sixth switch is configured to be open when the first switch is closed.

Example 7. The device of one of examples 1 to 6, where the fifth switch is configured to be open when the sixth switch is closed, and where the sixth switch is configured to be open when the fifth switch is closed.

Example 8. The device of one of examples 1 to 7, where the first and second terminals are terminals of an audio jack, where the first terminal is capable of providing a common voltage, and where the second terminal is capable of receiving a microphone audio signal.

Example 9. The device of one of examples 1 to 8, where the first terminal is configured to provide the common voltage, and the second terminal is configured to receive the microphone audio signal when the first switch is open, the second switch is closed, the third switch is closed, and the fourth switch is open.

Example 10. The device of one of examples 1 to 9, where: the third switch is capable of coupling an input crosstalk signal from the first terminal of the audio jack into the input of the amplifier, the amplifier is capable of providing an output crosstalk signal on the output of the amplifier based on the input crosstalk signal, and the second switch is capable of coupling the output crosstalk signal from the output of the amplifier into the microphone audio signal.

Example 11. The device of one of examples 1 to 10, further including: a first capacitor coupled between the third switch and the first terminal; and a second capacitor coupled between the fourth switch and the second terminal.

Example 12. The device of one of examples 1 to 11, where the input of the amplifier is a first input, the device further including a feedback path coupled between the output of the amplifier and a second input of the amplifier, where the feedback path includes first and second resistors, and first and second transistors or diodes.

Example 13. The device of one of examples 1 to 12, further including an audio processing front end circuitry having a first input coupled to the first terminal, and a second input coupled to the second terminal.

Example 14. A device including: a first terminal; an amplifier having an output and first and second inputs, the first input of the amplifier coupled to the first terminal; a feedback path coupled between the output of the amplifier and the second input of the amplifier; and a first transistor having a control terminal coupled to the first input of the amplifier, and a current path coupled between the second input of the amplifier and the first terminal.

Example 15. The device of example 14, where the feedback path includes a first resistor and a second transistor, where the first resistor and a current path of the second transistor are coupled in series between the output of the amplifier and the second input of the amplifier.

Example 16. The device of one of examples 14 or 15, further including a second resistor coupled in series with the current path of the first transistor.

Example 17. The device of one of examples 14 to 16, further including: a third transistor having a current path coupled between the first input of the amplifier and the second resistor, and a control terminal coupled to the first input of the amplifier; and a third resistor coupled in series with the current path of the third transistor.

Example 18. The device of one of examples 14 to 17, further including: a third transistor coupled to the second transistor; a first set of switches coupling the second transistor to the first resistor and to the third transistor; a second set of switches coupling the third transistor to the second transistor and to the first transistor; and a third set of switches coupling the first transistor to the third transistor and the second resistor, where the first, second, and third set of switches are configured to actuate according to a pattern to repeatedly change a sequence of the first, second, and third transistors in the current paths of the first and second transistors.

Example 19. The device of one of examples 14 to 18, where the feedback path includes multiple diode-connected transistors.

Example 20. The device of one of examples 14 to 19, further including a voltage source coupled to the first input of the amplifier.

Example 21. The device of one of examples 14 to 20, where the feedback path includes an equal number of transistors and resistors.

Example 22. The device of one of examples 14 to 21, further including: a second terminal; audio processing front end circuitry having a first input coupled to the first terminal, and a second input coupled to the second terminal; a first resistor coupled between the output of the amplifier and the second terminal; a first capacitor coupled between the first terminal and the first input of the amplifier; and a second capacitor coupled between the second terminal and the second input of the audio processing front end circuitry.

Example 23. The device of one of examples 14 to 22, further including: a first switch coupled between the first input of the amplifier and the first capacitor; a second switch coupled between the first input of the amplifier and the second capacitor; a third switch coupled in series with the first resistor; a second resistor coupled between the output of the amplifier and the first terminal; a fourth switch coupled in series with the second resistor; a fifth switch coupled between the current path of the first transistor and the first terminal; and a sixth switch coupled between the current path of the first transistor and the second terminal.

Example 24. A device, including: an audio jack port having first, second, third, and fourth terminals; an audio transmit circuit coupled to the first, second, and third terminals of the audio jack port and capable of providing first and second audio signals to the first and second terminals of the audio jack port, respectively, the third terminal of the audio jack port capable of providing a return path for the first and second audio signals; an audio receive circuit coupled to the third and fourth terminals of the audio jack port and capable of receiving a third audio signal from the fourth terminal of the audio jack port, the third terminal of the audio jack port capable of providing a return path for the third audio signal; a first capacitor coupled to the third terminal of the audio jack port and the audio receive circuit; a second capacitor coupled to the fourth terminal of the audio jack port and the audio receive circuit; and an amplifier having an input and an output, the input of the amplifier coupled to the first capacitor, and the output coupled to the second capacitor and the fourth terminal of the audio jack port.

Example 25. The device of example 24, where the third terminal is capable of receiving a crosstalk signal on the return path that is based on the first and second audio signals.

Example 26. The device of one of examples 24 or 25, where the output of the amplifier is capable of coupling the crosstalk signal into the third audio signal.

Example 27. The device of one of examples 24 to 26, where the input of the amplifier is a first input of the amplifier, and further including: a second input of the amplifier; and a feedback path between the output of the amplifier and the second input of the amplifier, the feedback path including multiple resistors and multiple transistors, the multiple transistors having approximately equal sizes and the multiple resistors having approximately equal resistances; and a transistor having a control terminal and first and second terminals, the control terminal of the transistor coupled to the first input of the amplifier, the first terminal of the transistor coupled to the feedback path and the second input to the amplifier, and the second terminal of the transistor coupled to the third terminal of the audio jack port.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail or more simply a “rail,” may also be referred to as a voltage terminal and may generally mean a common node or set of coupled nodes in a circuit at the same potential.

While this disclosure has been described with reference to illustrative examples, this description is not limiting. Various modifications and combinations of the illustrative examples, as well as other examples, will be apparent to persons skilled in the art upon reference to the description.

What is claimed is:

1. A device comprising:
first and second terminals;
an amplifier having an input and an output;
first and second switches coupled to the output of the amplifier;
a first resistor coupled between the first switch and the first terminal;
a second resistor coupled between the second switch and the second terminal;
a third switch coupled to the input of the amplifier; and
a fourth switch coupled to the input of the amplifier.

2. The device of claim 1, wherein the third switch is configured to be open when the fourth switch is closed, and wherein the fourth switch is configured to be open when the third switch is closed.

3. The device of claim 1, wherein the first switch is configured to be open when the second switch is closed, and wherein the second switch is configured to be open when the first switch is closed.

4. The device of claim 1, wherein the first and fourth switches are configured to be open when the second and third switches are closed, and wherein the second and third switches are configured to be open when the first and fourth switches are closed.

5. The device of claim 1, further comprising:
a fifth switch coupled between the first terminal and ground; and
a sixth switch coupled between the second terminal and ground.

6. The device of claim 5, wherein the fifth switch is configured to be open when the second switch is closed, and wherein the sixth switch is configured to be open when the first switch is closed.

7. The device of claim 5, wherein the fifth switch is configured to be open when the sixth switch is closed, and wherein the sixth switch is configured to be open when the fifth switch is closed.

8. The device of claim 1, wherein the first and second terminals are terminals of an audio jack, wherein the first terminal is capable of providing a common voltage, and wherein the second terminal is capable of receiving a microphone audio signal.

9. The device of claim 8, wherein the first terminal is configured to provide the common voltage, and the second terminal is configured to receive the microphone audio signal when the first switch is open, the second switch is closed, the third switch is closed, and the fourth switch is open.

10. The device of claim 8, wherein:
the third switch is capable of coupling an input crosstalk signal from the first terminal of the audio jack into the input of the amplifier,
the amplifier is capable of providing an output crosstalk signal on the output of the amplifier based on the input crosstalk signal, and
the second switch is capable of coupling the output crosstalk signal from the output of the amplifier into the microphone audio signal.

11. The device of claim 1, further comprising:
a first capacitor coupled between the third switch and the first terminal; and
a second capacitor coupled between the fourth switch and the second terminal.

12. The device of claim 1, wherein the input of the amplifier is a first input, the device further comprising a feedback path coupled between the output of the amplifier and a second input of the amplifier, wherein the feedback path comprises first and second resistors, and first and second transistors or diodes.

13. The device of claim 1, further comprising an audio processing front end circuitry having a first input coupled to the first terminal, and a second input coupled to the second terminal.

14. A device comprising:
a first terminal;
an amplifier having an output and first and second inputs, the first input of the amplifier coupled to the first terminal;
a feedback path coupled between the output of the amplifier and the second input of the amplifier; and
a first transistor having a control terminal coupled to the first input of the amplifier, and a current path coupled between the second input of the amplifier and the first terminal.

15. The device of claim 14, wherein the feedback path comprises a first resistor and a second transistor, wherein the first resistor and a current path of the second transistor are coupled in series between the output of the amplifier and the second input of the amplifier.

16. The device of claim 15, further comprising a second resistor coupled in series with the current path of the first transistor.

17. The device of claim 16, further comprising:
a third transistor having a current path coupled between the first input of the amplifier and the second resistor, and a control terminal coupled to the first input of the amplifier; and
a third resistor coupled in series with the current path of the third transistor.

18. The device of claim 16, further comprising:
a third transistor coupled to the second transistor;
a first set of switches coupling the second transistor to the first resistor and to the third transistor;
a second set of switches coupling the third transistor to the second transistor and to the first transistor; and
a third set of switches coupling the first transistor to the third transistor and the second resistor, wherein the first, second, and third set of switches are configured to actuate according to a pattern to repeatedly change a sequence of the first, second, and third transistors in the current paths of the first and second transistors.

19. The device of claim 14, wherein the feedback path comprises multiple diode-connected transistors.

20. The device of claim 14, further comprising a voltage source coupled to the first input of the amplifier.

21. The device of claim 14, wherein the feedback path comprises an equal number of transistors and resistors.

22. The device of claim 14, further comprising:
a second terminal;
audio processing front end circuitry having a first input coupled to the first terminal, and a second input coupled to the second terminal;
a first resistor coupled between the output of the amplifier and the second terminal;
a first capacitor coupled between the first terminal and the first input of the amplifier; and
a second capacitor coupled between the second terminal and the second input of the audio processing front end circuitry.

23. The device of claim 22, further comprising:
a first switch coupled between the first input of the amplifier and the first capacitor;
a second switch coupled between the first input of the amplifier and the second capacitor;
a third switch coupled in series with the first resistor;
a second resistor coupled between the output of the amplifier and the first terminal;
a fourth switch coupled in series with the second resistor;
a fifth switch coupled between the current path of the first transistor and the first terminal; and
a sixth switch coupled between the current path of the first transistor and the second terminal.

24. A device comprising:
an audio jack port having first, second, third, and fourth terminals;
an audio transmit circuit coupled to the first, second, and third terminals of the audio jack port and capable of providing first and second audio signals to the first and second terminals of the audio jack port, respectively, the third terminal of the audio jack port capable of providing a return path for the first and second audio signals;
an audio receive circuit coupled to the third and fourth terminals of the audio jack port and capable of receiving a third audio signal from the fourth terminal of the audio jack port, the third terminal of the audio jack port capable of providing a return path for the third audio signal;
a first capacitor coupled to the third terminal of the audio jack port and the audio receive circuit;
a second capacitor coupled to the fourth terminal of the audio jack port and the audio receive circuit; and
an amplifier having an input and an output, the input of the amplifier coupled to the first capacitor, and the output coupled to the second capacitor and the fourth terminal of the audio jack port.

25. The device of claim 24, wherein the third terminal is capable of receiving a crosstalk signal on the return path that is based on the first and second audio signals.

26. The device of claim 25, wherein the output of the amplifier is capable of coupling the crosstalk signal into the third audio signal.

27. The device of claim 24, wherein the input of the amplifier is a first input of the amplifier, and further comprising:
a second input of the amplifier; and
a feedback path between the output of the amplifier and the second input of the amplifier, the feedback path including multiple resistors and multiple transistors, the multiple transistors having approximately equal sizes and the multiple resistors having approximately equal resistances; and
a transistor having a control terminal and first and second terminals, the control terminal of the transistor coupled to the first input of the amplifier, the first terminal of the transistor coupled to the feedback path and the second input to the amplifier, and the second terminal of the transistor coupled to the third terminal of the audio jack port.
